(19) United States
(12) Patent Application Publication
(10) Pub. No.: US 2023/0127237 A1
(43) Pub. Date: Apr. 27, 2023

(54) INTEGRATING WELLS INTO ADAPTIVE MULTI-SCALE GEOLOGICAL MODELING

(71) Applicant: Saudi Arabian Oil Company, Dhahran (SA)

(72) Inventor: Simon A. Stewart, Dhahran (SA)

(21) Appl. No.: 17/510,998

(22) Filed: Oct. 26, 2021

(51) Int. Cl. G01V 1/28; G06F 30/20; G01V 1/30

(52) U.S. Cl. CPC G01V 1/282; G06F 30/20; G01V 1/301

(57) ABSTRACT

Methods and systems, including computer programs encoded on a computer storage medium can be used for adaptive multi-scale geological modeling and well integration. The systems and methods are used to integrate seismic mapping data and well data for a subsurface region that includes a reservoir. The specification describes an example algorithm that is used to adaptively identify and isolate natural length scales in a seismic map. The identified natural length scales are then used to determine appropriate filtering of well information and ultimately achieve an automatic integration of orientation information from seismic map and well information.

### TECHNICAL FIELD

This specification relates to integrating wells into geological modeling.

### BACKGROUND

In geology, sedimentary facies are bodies of sediment that are recognizably distinct from adjacent sediments that resulted from different depositional environments. Generally, geologists distinguish facies by aspects of the rock or sediment being studied. Seismic facies are groups of seismic reflections whose parameters (such as amplitude, continuity, reflection geometry, and frequency) differ from those of adjacent groups. Seismic facies analysis is a subdivision of seismic stratigraphy, plays an important role in hydrocarbon exploration, and is one key step in the interpretation of seismic data for reservoir characterization. The seismic facies in a given geological area can provide useful information, particularly about the types of sedimentary deposits and the anticipated lithology.

In reflection seismology, geologists and geophysicists perform seismic surveys to map and interpret sedimentary facies and other geologic features for applications such as identification of potential petroleum reservoirs. Seismic surveys are conducted by using a controlled seismic source (for example, a seismic vibrator or dynamite) to create a seismic wave. In land-based seismic surveys, the seismic source is typically located at ground surface. The seismic wave travels into the ground, is reflected by subsurface formations, and returns to the surface where it is recorded by sensors called geophones. Other approaches to gathering data about the subsurface, such as information relating to wells or well logging, can be used to complement the seismic data.

Reservoir models based on data about the subterranean regions can be used to support decision-making relating to field operations.

### SUMMARY

This document describes an automated (or user constrained) map-making technique that uses unguided scale isolation and integration of seismic mapping and well information to increase the accuracy of subsurface structural maps. The techniques disclosed in this document include an adaptive algorithm that can automatically optimize and combine multi-scale generalizations of seismic maps and well information. For example, the adaptive algorithm can identify relevant length scales and achieve alignment of seismic depth map to well information based on a combination of existing analytical tools.

The techniques are useful for reducing or removing errors and distortions of true structures that can occur when mapped geological structures between wells of a subsurface region are processed using depth conversion methods. The adaptive algorithm can automatically identify relevant length scales and tie a seismic depth map to well information. The adaptive algorithm can be used in combination with various analytical tools to provide the identified length scales and consistency between seismic depth maps and corresponding well data.

One aspect of the subject matter described in this specification can be embodied in a computer-implemented method for integrating seismic mapping data and well data for a subsurface region comprising a reservoir. The method includes determining first length scales of the seismic mapping data; extracting a respective structure at each of the first length scales; and generating a filtered structural map using the extracted structures for each of the first length scales. The method further includes determining structural amplitudes of the extracted structures based on a curvature analysis performed on the filtered structural maps; filtering information included in the well data using second length scales determined from the structural amplitudes of the extracted structures; and determining, for the well data and based on an optimization scheme, one or more structural corrections that: i) account for multi-scale structures of the subsurface region, and ii) ties the seismic mapping data to the well data. The method includes integrating the seismic mapping data and the well data based at least on the filtered information, the structural amplitudes, and the structural corrections. The method includes generating an output representing the integrated seismic mapping data and the well data.

These and other implementations can each optionally include one or more of the following features. For example, in some implementations, generating an output representing the integrated seismic mapping data and the well data includes: generating an integrated map of subsurface structures with structural information at a user-specified length scale, where the integrated map matches relevant structural depths and orientation information in wells that are located in an area of the subsurface region represented by the integrated map.

In some implementations, integrating the seismic mapping data and the well data includes: obtaining, from the filtered information included in the well data, structural information at a particular vertical length scale associated with a well; tying a seismic map of a corresponding horizontal length scale to the well at least by matching an orientation at a position of the well on the seismic map; and integrating the seismic mapping data and the well data at least by tying the seismic map of the corresponding horizontal length scale to the well.

Integrating the seismic mapping data and the well data can include: modifying a depth map derived from seismic interpretation over an area including the subsurface region, wherein the depth map is modified using depth and structural orientation information of the well data. In some implementations, the seismic mapping data includes a mapped geological structure that is intermediate one or more wells and the method further includes: integrating the seismic mapping data and the well data without distorting a true structure of the mapped geological structure.

In some implementations, determining one or more structural corrections includes: determining one or more length-scale specific structural orientation corrections. Determining first length scales can include: performing scale selection analysis on the seismic mapping data; and determining multiple dominant length scales based on the scale selection analysis. Determining one or more structural corrections includes: calculating a single representative correction that accounts for the multiple dominant length scales.

In some implementations, the method further includes: applying a multi-objective optimization scheme to the filtered information derived from the well data; and in response to applying the multi-objective optimization scheme, minimizing a correction factor across each of the second length scales. Extracting a respective structure at each of the first length scales can include: applying a spatial filtering technique to the seismic mapping data with reference to the first length scales; and extracting a respective structure at each of the first length scales in response to applying the spatial filtering technique to the seismic mapping data. The spatial filtering technique can include a bandpass filter.

In some implementations, the seismic mapping data includes a map of subsurface structures in the form of a depth grid that is referenced to x,y spatial coordinates; and the well data includes well control locations with depth-dependent structures in the form of structural dip and dip direction. In some implementations, generating an output representing the integrated seismic mapping data and the well data includes: generating an imaging of subsurface geology for applications in: i) hydrocarbon production using the reservoir, ii) aquifer management, and iii) sequestration projects.

Other implementations of this and other aspects include corresponding systems, apparatus, and computer programs, configured to perform the actions of the methods, encoded on computer storage devices. A computing system of one or more computers or hardware circuits can be so configured by virtue of software, firmware, hardware, or a combination of them installed on the system that in operation cause the system to perform the actions. One or more computer programs can be so configured by virtue of having instructions that are executable by a data processing apparatus to cause the apparatus to perform the actions.

The subject matter described in this specification can be implemented to realize one or more of the following advantages.

This specification discloses systems and methods for tackling unguided scale isolation and integration of seismic mapping and well information. Relative to conventional approaches, the disclosed techniques can improve overall efficiency of a mapping process in subsurface projects. An example hardware computing system can implement these techniques to identify and account for structural geometry of a reservoir while integrating seismic and well data for those structures into an example depth map. The structural geometry can include structural orientation information in wells, as well as multi-scale structures of wells or seismic maps. The disclosed methods effectively recognize and account for the different scales associated with these structures when integrating wells with maps.

More specifically, the specification discloses a map-making technique operable to increase an accuracy of subsurface structural maps at least by automatically optimizing and combining multi-scale generalizations of seismic maps and well information. The disclosed techniques provide an example algorithm that can be used to adaptively identify and isolate natural length scales in a seismic map. The identified natural length scales are then used to determine appropriate filtering of well information and ultimately achieve an automatic integration of orientation information from seismic map and well information.

The disclosed data integration techniques can allow for more effective use of existing well databases or information sets to enhance the accuracy of maps used for hydrocarbon and sequestration purposes, including related activities surrounding prospect generation, positioning of exploration wells, subsurface mapping, and booking of hydrocarbon resources. As indicated earlier, if desired, an example system can implement these techniques without user intervention, adaptively selecting appropriate parameters to deliver final integrated maps, thus enabling more efficient workflows by untying individual users from some (or all) of the decision making processes.

The details of one or more embodiments of these systems and methods are set forth in the accompanying drawings and the following description. Other features, objects, and advantages of these systems and methods will be apparent from the description and drawings, and from the claims.

### BRIEF DESCRIPTION OF THE DRAWINGS

This application contains at least one drawing executed in color. Copies of this application with color drawing(s) will be provided by the Patent Office upon request and payment of the necessary fee.

FIG. 1 is a schematic view of a seismic survey being performed to map subterranean features such as facies and faults.

FIG. 2 illustrates an example computing system for generating an integrated data output.

FIG. 3 illustrates an example method for adaptive map-to-well structural integration.

FIG. 4 illustrates an example process for performing data integration using the example algorithm of FIG. 3.

FIGS. 5A-5C illustrate example curvature and scale space data for a subsurface region.

FIGS. 6A and 6B illustrate example scale data for a subsurface region.

FIG. 7 is example data showing length scale isolation.

FIGS. 8A-8D illustrate example information and data associated with curvature analysis of a length scale filtered surface.

FIG. 9A shows example data for a geological layer orientation.

FIG. 9B shows example information for a geological structure.

FIG. 10 shows an example graphical interface of an application that integrates structural data.

FIG. 11 is a block diagram illustrating an example computer system used to provide computational functionalities associated with described algorithms, methods, functions, processes, flows, and procedures according to some implementations of the present disclosure.

Like reference numbers and designations in the various drawings indicate like elements.

### DETAILED DESCRIPTION

Reflection seismic data is a standard tool for imaging subsurface geology for applications in hydrocarbon production, aquifer management and sequestration projects. Interpretations of this data are transformed into depth maps via depth conversion procedures that include correcting depth to a ground-truth provided by drilled wells. Because drilled wells can be spaced widely (for example, many kilometers apart), mapping geological structures between wells relies on depth conversion methods that are subject to error. The errors can distort the true structural (or spatial characteristic) of the geological structure, which is referred to as structural distortion. In some cases, obtaining incorrect volume estimates of a subsurface hydrocarbon resource or greenhouse gas storage potential is an example penalty of between-well structural distortion.

In certain structural configurations, such as low-relief closures, this error can range up to one hundred percent of mapped volume. One conventional solution is to increase the radius of influence of well information into between-well areas that are mapped only with the depth-converted seismic method. A barrier to this integration approach is the multi-scale characteristic of structural orientation information in the horizontal (seismic mapping) and vertical (wells) directions. To date, this barrier or multi-scale characteristic has limited implementation of the increased radius solution in existing workflows or software solutions. The multi-scale nature of subsurface structural information ranges from noise to superposition of real geological structures of different origins and length scales. In general, the multi-scale nature of subsurface structural information presents mappers with substantial challenges.

In view of the above, this specification describes an adaptive algorithm designed to automatically identify relevant length scales and achieve a tie of seismic depth map to well information using a combination of existing analytical tools. Seismic depth maps can be tied to the correct depth as seen in drilled wells using an example analytical procedure. This is achieved, for example, by calculating the discrepancy between the actual depth of a given geological horizon seen in a well, versus the depth of that horizon at the well location in the seismic depth map. This discrepancy is a depth error that is corrected by adding or subtracting the discrepancy to the depth map so that the map “ties” the well.

For example, when the map “ties” the well the corrected map contains exactly the same depth at the well location as was seen for the geological layer represented by the map, within the well itself. Such corrections can be applied within a user-specified area of influence, within which the discrepancy correction decays radially away from the well to zero at some specified distance, in order to avoid correction anomalies or discontinuities in the map structure near the wells. An example radius of influence would be one to five kilometers to achieve a smooth depth correction. This procedure can be done manually, or automatically in standard petro-technical mapping computer applications.

The algorithm is used to determine the dominant length scales of a structure at least based on scale selection analysis of the seismic map. To isolate structures at these scales, the algorithm includes executing bandpass filtering in response to the scale selection analysis of the seismic map. The isolated structures can correspond to filtered structural maps. The algorithm includes a step to implement curvature analysis of the filtered structural maps. The curvature analysis is used to determine structural amplitudes, which are used to determine length scales for filtering the well information.

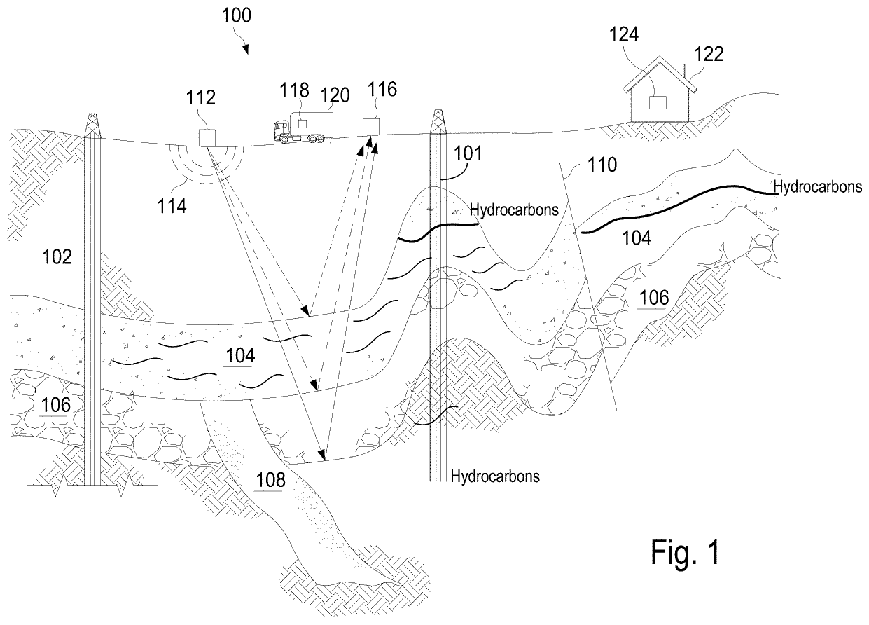

FIG. 1 is a schematic view of a seismic survey being performed to map subterranean features such as facies and faults in a subterranean formation 100. FIG. 1 shows an example of acquiring seismic data using an active source 112. This seismic survey can be performed to obtain seismic data (such as acoustic data) used to generate a depth map in the subterranean formation 100. The subterranean formation 100 includes a layer of impermeable cap rock 102 at the surface. Facies underlying the impermeable cap rocks 102 include a sandstone layer 104, a limestone layer 106, and a sand layer 108. A fault line 110 extends across the sandstone layer 104 and the limestone layer 106.

Oil and gas tend to rise through permeable reservoir rock until further upward migration is blocked, for example, by the layer of impermeable cap rock 102. Seismic surveys attempt to identify locations where interaction between layers of the subterranean formation 100 are likely to trap oil and gas by limiting this upward migration. For example, FIG. 1 shows an anticline trap 107, where the layer of impermeable cap rock 102 has an upward convex configuration, and a fault trap 109, where the fault line 110 might allow oil and gas to flow in with clay material between the walls traps the petroleum. Other traps include salt domes and stratigraphic traps.

In some contexts, such as shown in FIG. 1, an active seismic source 112 (for example, a seismic vibrator or an explosion) generates seismic waves 114 that propagate in the earth. Although illustrated as a single component in FIG. 1, the source or sources 112 are typically a line or an array of sources 112. The generated seismic waves include seismic body waves 114 that travel into the ground and seismic surface waves that travel along the ground surface and diminish as they get further from the surface.

The velocity of these seismic waves depends properties, for example, density, porosity, and fluid content of the medium through which the seismic waves are traveling. Different geologic bodies or layers in the earth are distinguishable because the layers have different properties and, thus, different characteristic seismic velocities. For example, in the subterranean formation 100, the velocity of seismic waves traveling through the subterranean formation 100 will be different in the sandstone layer 104, the limestone layer 106, and the sand layer 108. As the seismic body waves 114 contact interfaces between geologic bodies or layers that have different velocities, each interface reflects some of the energy of the seismic wave and refracts some of the energy of the seismic wave. Such interfaces are sometimes referred to as horizons.

During some fracking contexts, rather than an active source 112, a hydraulic fracturing fluid, such as water with minerals included, is pumped into the wellbore and is used to generate vibrations in the subsurface. In some examples, the vibrations caused by the injection of the fluid can be used to obtain vibration data from the subsurface. This is a passive data acquisition approach. Rather than generating seismic body waves 114, the passive approach generates guided tube waves which are used to measure the fractures in the subsurface. In the context of FIG. 1, an active source 112 can be used to map the subsurface either individually or in combination with the passive sources.

The seismic waves 114 are received by a sensor or sensors 116. Although illustrated as a single component in FIG. 1, the sensor or sensors 116 generally include one to several three-component sensors that are positioned near an example wellhead. The sensors 116 can be geophone-receivers that produce electrical output signals transmitted as input data, for example, to a computer 118 on a seismic control truck 120. Based on the input data, the computer 118 may generate a seismic data output, for example, a seismic two-way response time plot.

The sensors 116 are generally housed in a modular unit on or near the wellhead. The recorded seismic data are transmitted to nearby processing center (such as center 122 subsequently described) using wireless transmission. Because the recorded seismic data includes only one or several channels, depending on the number of the sensors 116, the data size of the seismic data is very small relative to seismic data gathered from dense 3D sensor arrays typical for SWF contexts. This is true even after the sensors 116 are recording continuously for several days. Therefore, data processing and delivery are relatively efficient compared to data produced by the dense 3D sensor arrays. The smaller data size enables real-time monitoring of the hydraulic fractures of the environment 100.

A control center 122 can be operatively coupled to the seismic control truck 120 and other data acquisition and wellsite systems. The control center 122 may have computer facilities for receiving, storing, processing, and analyzing data from the seismic control truck 120 and other data acquisition and wellsite systems that provide additional information about the subterranean formation. For example, the control center 122 can receive data from a computer associated with a well logging unit. For example, computer systems 124 in the control center 122 can be configured to analyze, model, control, optimize, or perform management tasks of field operations associated with development and production of resources such as oil and gas from the subterranean formation 100. Alternatively, the computer systems 124 can be located in a different location than the control center 122. Some computer systems are provided with functionality for manipulating and analyzing the data, such as performing seismic interpretation or borehole resistivity image log interpretation to identify geological surfaces in the subterranean formation or performing simulation, modeling, data integration, planning, and optimization of production operations of the wellsite systems.

In some embodiments, results generated by the computer systems 124 may be displayed for user viewing using local or remote monitors or other display units. One approach to analyzing seismic data is to associate the data with portions of a seismic cube representing the subterranean formation 100. The seismic cube can also be display results of the analysis of the seismic data associated with the seismic survey. The results of the survey can be used to generate a geological model representing properties or characteristics of the subterranean formation 100.

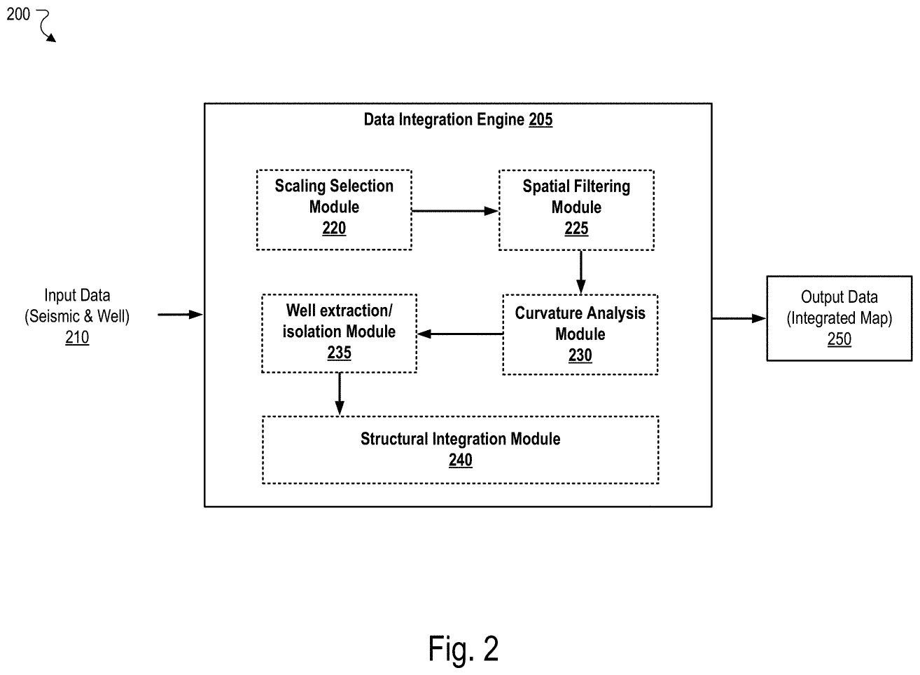

FIG. 2 illustrates an example computing system 200 that includes a data integration engine 205 (“data integration engine 205”).

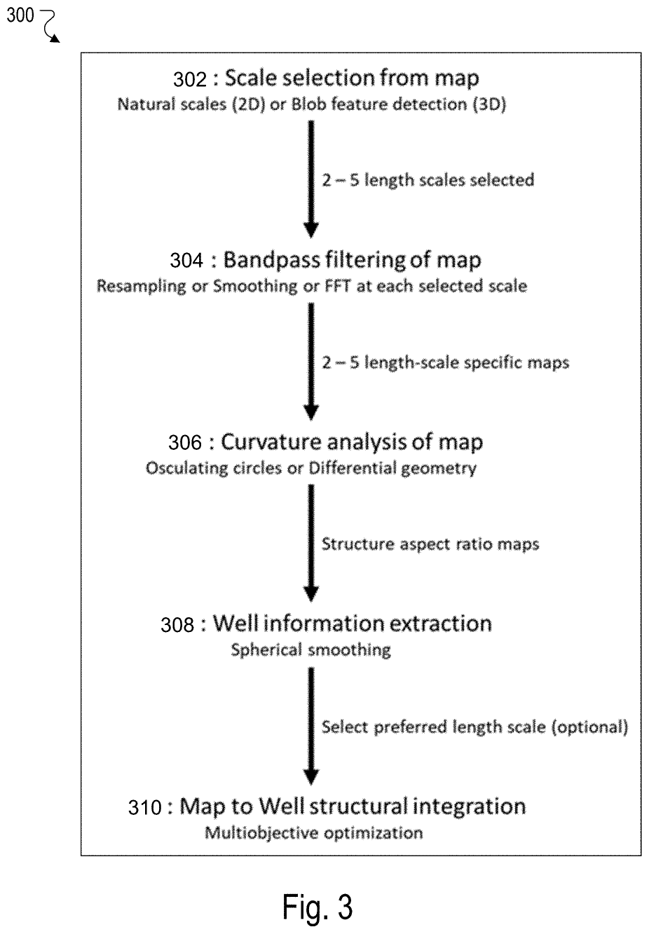

The data integration engine 205 of system 200 executes an example adaptive algorithm to tackle and address unguided scale isolation and integration of seismic mapping and well information. The algorithm can be implemented at system 200 in a fully automatic form or in such a way that user input can constrain decisions and outputs of the algorithm. For example, the algorithm can be implemented to run automatically from start to finish, with minimal or no user intervention. In some implementations, the algorithm is an adaptive data integration algorithm that is executed in an artificial intelligence (AI) or machine-learning based implementation. The algorithm can be constrained by user input/guidance at a particular stage of the algorithm's processing pipeline. As indicated at the example of FIG. 3, an implementation of the algorithm can be split into, or divided among, five separate compute modules or application programs. This implementation of the algorithm can also be executed fully automatically or with complete (or partial) user control with regard to parameter values and overall utilization.

Relative to conventional approaches, the use of system 200 and its implementation of the example adaptive algorithm can improve overall efficiency of a mapping process in subsurface projects. The algorithm is described in more detail later with reference to FIG. 3.

The data integration engine 205 is configured to implement techniques for analysis and integration of seismic and well data in the context of geophysical and geologic prospecting or modeling. More specifically, the data integration engine 205 is configured to integrate seismic data and well data and generate an integrated output 250 that accurately accounts for the different scales (e.g., structural wavelength) of geological structures in each dataset. The data integration engine 205 generates the integrated output in response to processing an example input dataset 210 of seismic and well data. In some implementations, the output generated by the data integration engine 205 is an integrated map for adaptive multi-scale geological modelling and well integration. For example, the output data or integrated map may be used to obtain or model properties of a subsurface region such as a hydrocarbon reservoir.

Each of system 200 and the data integration engine 205 may be included in the computer system 124 described earlier with reference to FIG. 1. For example, each of system 200 and the data integration engine 205 can be included in the computer system 124 as a sub-system of hardware circuits, such as a special-purpose circuit, that includes one or more processor microchips. Although a single data integration engine 205 is shown in the example of FIG. 2, in some cases the computer systems 124 can include multiple data integration engines 205 as well as multiple systems 200. Each of the data integration engines 205 can include processors, for example, a central processing unit (CPU) and a graphical processing unit (GPU), memory, and data storage devices.

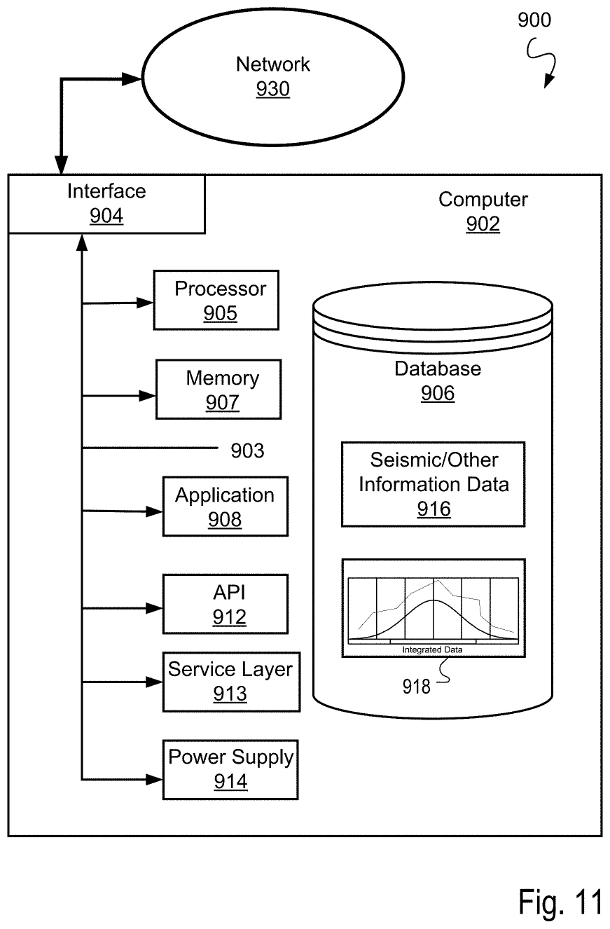

In some implementations, the system 200 is an example computing or data processing device, such as a machine-learning engine included in the computer system 124 described earlier with reference to FIG. 1. For example, the computing device can be a special-purpose hardware integrated circuit of the computer system 124, and which includes one or more processor microchips. The computing device can also be included in a computer system 900, which is described later with reference to FIG. 11. The special-purpose circuitry can be used to execute machine-learning algorithms corresponding to learning or inference techniques that are implemented using, for example, neural networks or support vector machines. In general, the computing device can include processors, for example, a graphics-processing unit (GPU) or neural network processor, memory, and data storage devices that collectively form one or more computing devices of computer systems 124.

In some implementations, the system 200 includes, or is used to generate, predictive models for modeling properties and characteristics of a subterranean or subsurface region. The predictive models can be used for modeling reservoir behavior in support of decision making relating to field operations. The predictive models can perform their modeling operations based on example multi-scale integrated geological maps that are generated using the data integration engine 205. In some cases, the system 200 can use the data integration engine 205 to model, infer, or otherwise predict various conditions and properties of a hydrocarbon reservoir or subsurface region. A specific high-impact example implementation of multi-scale integration is where the structural relief, e.g., elevation of geological structure from its crest to lowest closing contour, is of the same magnitude as the depth discrepancy in a newly-drilled well. In this implementation, matching the area of influence of a correction factor, using the natural scale in the seismic map, to the correction itself incorporating structural orientation information at natural scale from the well data set, achieves an update to the seismic map that is accurate at some distance from the newly-drilled well. The between-well accuracy is used to determine fluid volumes represented by the geological structure of the seismic map, and selecte locations for yet-to-be-drilled wells that have specific well objectives.

A map, such as a seismic map, may be a required input in a computational process for drilling decisions. An example map can include numerical grids that are produced from geological and geophysical data. For example, numerical grids for a map can be produced specifically from well formation depths and seismic data. The data integration engine 205 can represent mapping software or an example data model that is used to process sets of input data that include information about properties of a subsurface formation. In some implementations, the seismic data is initially acquired in the time domain and processed to obtain a corresponding spatial representation as well as any appropriate de-noising of the acquired seismic signals.

Interpretations of this seismic data can be transformed into depth maps via an example depth conversion procedure. For example, the depth conversion process can rely on velocity models that are guided by information derived from seismic processing and, where available, drilled wells. For areas between well control locations, velocity models are non-unique and their finalized maps often contain distortions of actual, real-world structures. In some cases, the distortions are only revealed when new wells are drilled. These distortions give incorrect estimates of resource potential, which often cause major revisions to production or injection projects when the errors are identified by later wells. At this later point of identification significant resources and expectations may have already committed (for example, over- or under-committed) to the project.

To address these challenges, this specification describes a solution that allows for maximizing the influence of existing wells by utilizing depth and structural orientation information in those wells (for example, some or all information) to modify a depth map produced from seismic interpretation over as wide an area as reasonably possible. Well (or wellbore) orientation can be described in terms of inclination and azimuth. Inclination can refer to a vertical angle measured from the down direction—the down, horizontal and up directions have inclinations of 0°, 90° and 180°, respectively. Azimuth can refer to the horizontal angle measured clockwise from true north—the north, east, south and west directions have azimuths of 0°, 90°, 180° and 270°, respectively.

As described below, seismic data can include mapped geological structures that are contained within an area drilled by one or more wells. For example, it is rare that a well finds the structure exactly as mapped pre-well. So, unless the existing well control is very close to the new well, a correction factor is often required, e.g., to remove distortion. In view of this, this disclosure presents techniques for determining and applying appropriate correction factors to correct the seismic map in an area of influence determined by the natural scale. For example, the data integration engine 205 can implement one or more of these techniques to determine the required correction factors that achieve more effective structural orientations and radius of influence as well as depth correction in a particular area. In some cases, if there are several natural scales, the data integration engine 205 is operable to determine and/or select scales that are closest in magnitude to structural scales of commercial significance.

The data integration engine 205 employs an adaptive algorithm that overcomes the existing challenge of integrating local orientation information into a wide-ranging map. For example, the disclosed techniques can overcome an existing barrier where data integration methods are limited due to their inability to account for the multi-scale character of both the map and well data. The approach described in this document avoids the use of unfiltered map or well data, which gives an uncontrolled and effectively meaningless product. This effect, combined with the laborious process of searching scale space for information at an appropriate length scale, discourages mappers from using available integration tools.

Referring again to FIG. 2, the data integration engine 205 includes a scaling selection module 220, a spatial filtering module 225, a curvature analysis module 230, a well extraction/isolation module 235, and a structural integration module 240. As described in detail later, the scaling selection module 220, the spatial filtering module 225, the curvature analysis module 230, the well extraction/isolation module 235, and the structural integration module 240 interact and cooperate to maximize the influence of existing wells by utilizing depth and structural orientation information in those wells to modify a depth map produced from seismic interpretation over a wide area. Each of these computing modules are described later with reference to the example algorithm of FIG. 3.

Further, as used in this specification, the term “module” is intended to include, but is not limited to, one or more computers configured to execute one or more software programs that include program code that causes a processing unit(s) of the computer to execute one or more functions. The term “computer” is intended to include any data processing device, such as a desktop computer, a laptop computer, a mainframe computer, an electronic notebook device, a computing server, a smart handheld device, or other related device able to process data.

FIG. 3 illustrates an example method or workflow that includes an algorithm 300 used for adaptive map-to-well structural integration. The algorithm 300 can be used, for example by subsurface mappers, to automatically achieve an accurate final depth map product. In some cases, the accurate final depth maps are achieved with variable amounts of machine assistance. In practice, the algorithm can be implemented as a software solution via specially coded application programs, such as “apps,” making use of standard or special-purpose hardware. The algorithm 300 achieves the depth map products at least by selecting appropriate length scale information from seismic mapping data. The appropriate length scales are selected to facilitate datasets associated with wells of a mapped region, where the datasets have appropriate areas of influence on the seismic map.

An example of a natural length scale is a geological structure apparent at a spatial length scale of, for example, one to ten kilometers. This scale can be determined based on the natural spacing of controlling geological phenomena such as fault spacing in areas of the Earth's crust that underlie sedimentary basins. In some implementations, this scale is used for applications such as oil and gas Exploration and CO2 sequestration at least because it incorporates the size range of structures that are large enough to trap commercially significant fluid volumes, but small enough to exist as discrete, self-contained structures within larger-scale structures such as sedimentary basins. A further example would be the length scale of sedimentary basins, which can be ten to hundreds of kilometers spatial wavelength, governed by processes involving flexure of the Earth's crust.

In some implementations, the input 210 to data integration engine 205 and algorithm 300 includes a map of, or mapping data for, a subsurface structure, including well information. The input data 210 may be in the form of a depth grid referenced to X,Y spatial coordinates. For instance, the spatial coordinates can be in the UTM (Universal Transverse Mercator) Coordinate Reference System, and well information consisting of well location with depth-dependent structure in the form of structural dip and dip direction. As described earlier, the data integration engine 205 is configured to generate an output 250, which can be a map of subsurface structure with structural information at the desired length scale. That integrated output map 250 will match (or substantially match) the relevant structural depth and orientation information in wells that are located in the area represented by the input map (for example, a seismic map).

FIG. 3 shows that in algorithm 300, as an initial step, the data integration engine 205 uses the scale selection module 220 to implement a step of the algorithm 300 that includes performing scale selection (302).

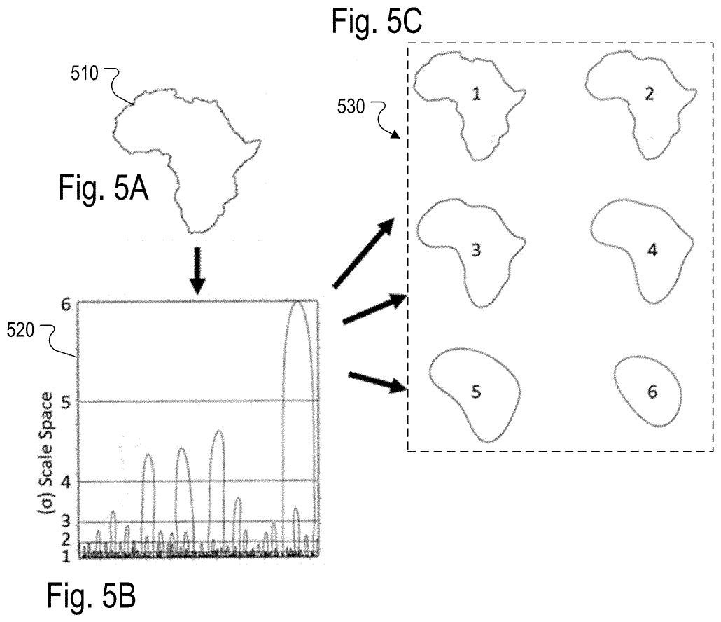

Without a prior knowledge of the dominant length scale of a structure in a subsurface layer mapped from seismic reflection data, it is necessary to determine which scales of structure are present. There are many techniques available to isolate dominant scales from curves, images or surfaces. Such techniques can be applied by treating cross section information, that can be extracted from a given two-dimensional (2D) seismic line or interpretation drawn from a three-dimensional (3D) seismic volume, as curves that can be subject to a scale space analysis. Example illustrations for this concept are discussed later with reference to FIG. 5.

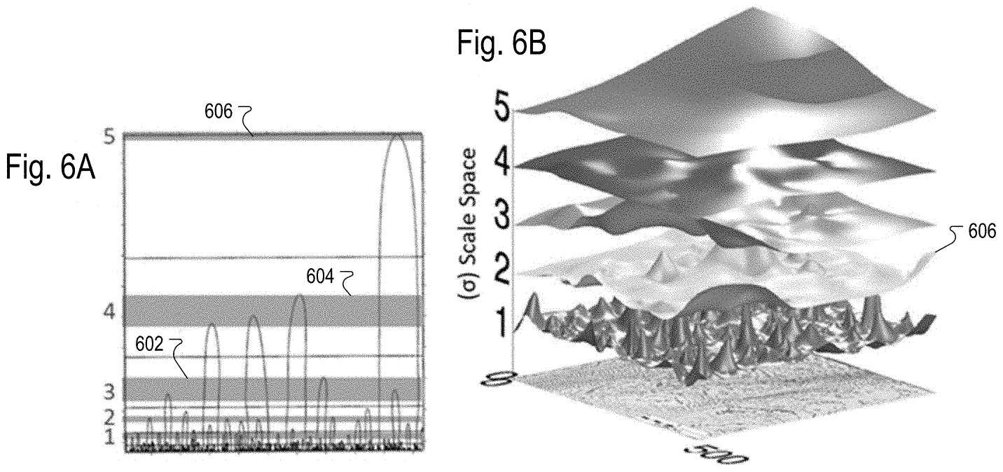

An example technique could be natural scale extraction. Alternatively, a 3D map could be used directly in a blob feature detection analysis. Example illustrations for this concept are discussed later with reference to FIG. 6. Natural scale and blob feature detection both use the technique of using clusters of structure annihilation in scale space to identify dominant, or natural scales. This technique is well-known in the field of computer vision. Scale selection from a map made from reflection seismic data, given the information restrictions imposed by the usual spatial sampling of 12.5 m or 25 m, will usually return 2 to 5 dominant scales.

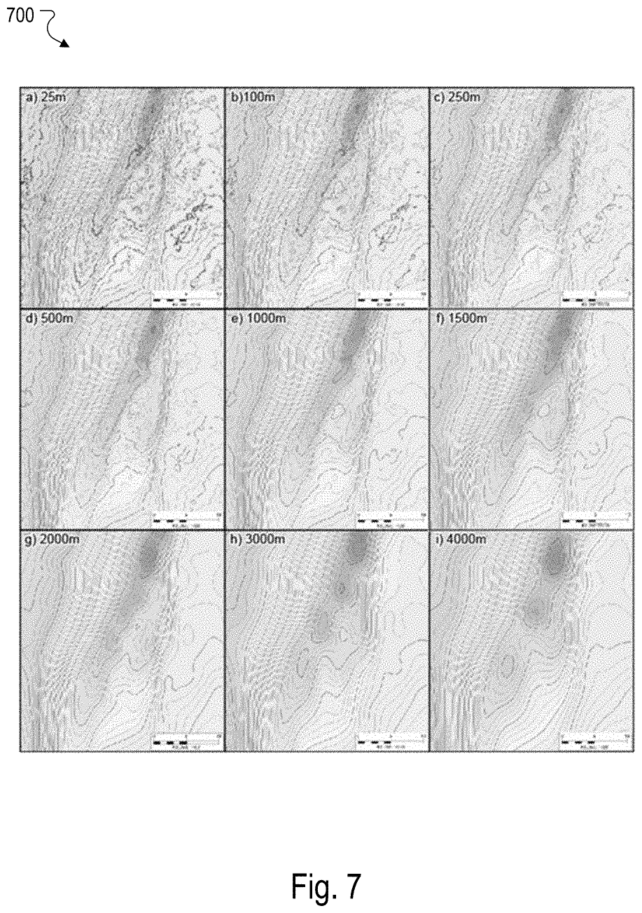

The spatial filtering module 225 is used to perform a step of the algorithm 300 that includes filtering operations for isolating geological structures at a given scale (304). For example, the spatial filtering module 225 can implement one of multiple techniques for isolating geological structures at a given scale from a dataset that describes a curve (2D) or surface such as a structural map (3D). These include, but are not limited to, resampling, smoothing and Fast Fourier Transforms, or combinations thereof. Example illustrations for this filtering concept are discussed later with reference to FIG. 7. The spatial filtering module 225 applies a spatial filtering technique to generate versions of the structural map with information content restricted to the spatial length scales identified in (302).

The curvature analysis module 230 is used to perform a step of the algorithm 300 that pertains to curvature analysis (306). As indicated earlier, an objective of algorithm 300 is to integrate map and well information, with a particular focus on structural orientation. The true depth of a surface represented by the map, as seen in the well, can be combined by the data integration engine 205 at least shifting the structural map to the well depth at the point of intersection, with the shift magnitude decreasing radially away from the point of intersection according to some proscribed function. However, integration of the orientation information can be difficult due to the multi-scale nature of the information in the map and well domains. For example, the difficultly can be attributed to a lack of known physical laws or proofs that relate horizontal length scale of a structure (as seen on maps) to a corresponding vertical length scale of a structure (as seen in wells).

A convenient approximation is to use the geological structure aspect ratio to determine the length scale at which to extract orientation information from the well, taking advantage of the horizontal length scale(s) having been identified at (302) and (304). In general, the aspect ratio of a geometric shape or geological structure can be the ratio of its sizes in different dimensions.

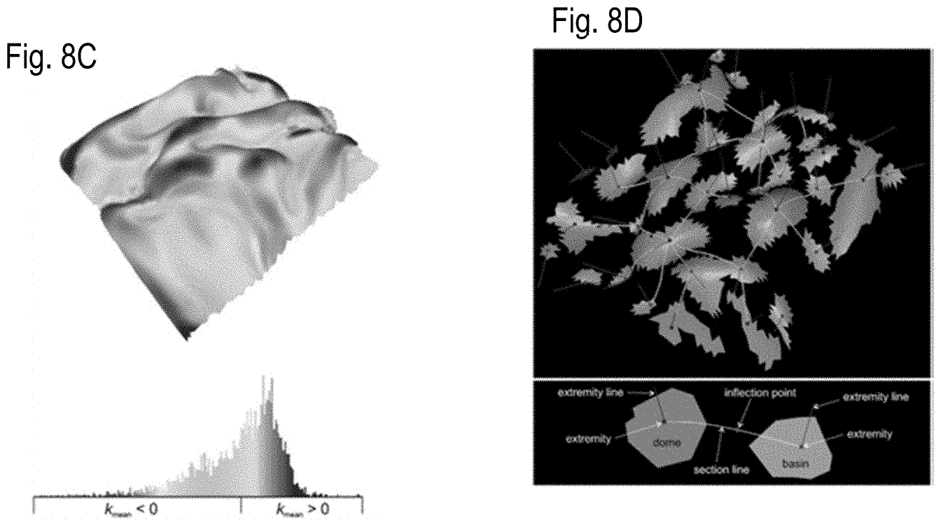

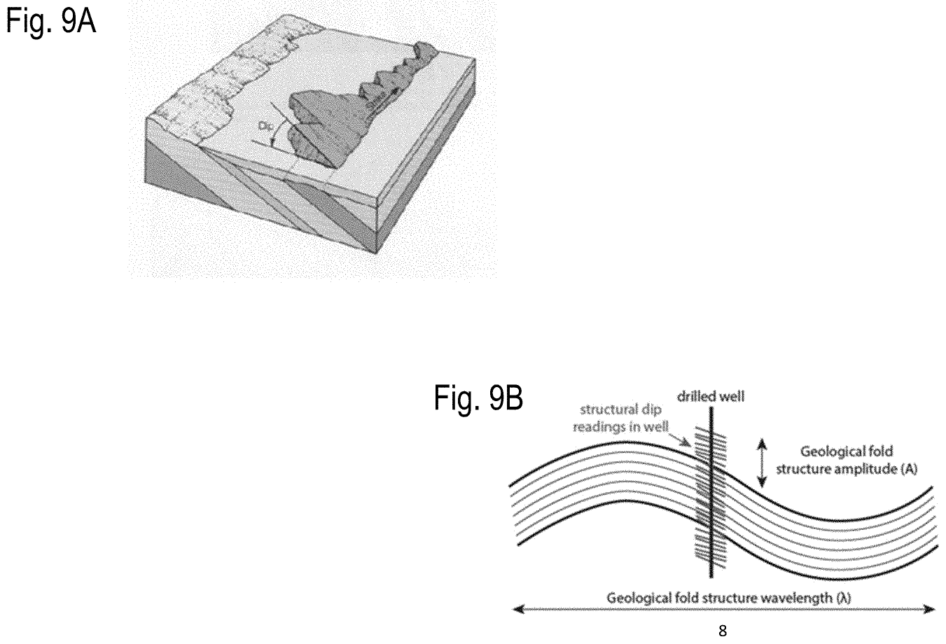

Justification for this approximation is that the geological length scales of subsurface structures that are of commercial interest in sedimentary basins, such as oil and gas, aquifer or sequestration projects, tend to have long spatial length scales (kilometers to tens of kilometers) while the amplitudes are relatively low (hundreds of meters). In these cases, the vertical and horizontal length scales must be different for a given structure, because the scale of layering in the basin is less than the horizontal length scale. An example illustration indicating structural amplitudes is discussed later with reference to FIGS. 9A-9B.

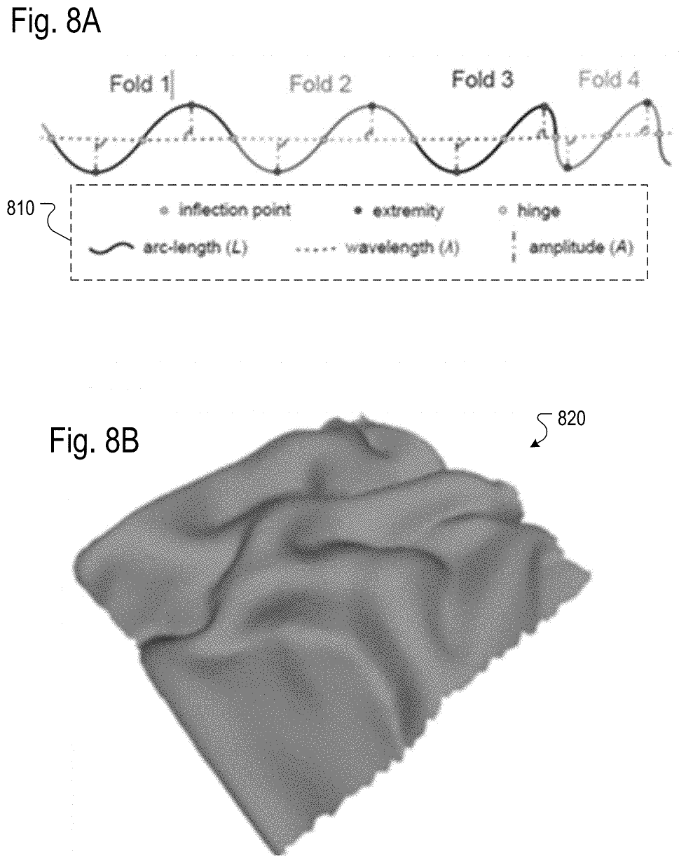

Geological fold structures can be described according to aspect ratio defined as the ratio of structural amplitude to wavelength. Example illustrations that indicate these concepts are discussed later with reference to FIGS. 8 and 9. Since the structural wavelengths and amplitudes, and hence aspect ratios at a given length scale, can be isolated by curvature analysis, an approximation of vertical length scale can be obtained from a map of structural aspect ratio based on curvature analysis. Example illustrations that indicate this concept are discussed later with reference to FIGS. 8A-8D. Structural aspect ratio can vary across a surface that represents a given length scale. The data integration engine 205 can use the curvature analysis module 230 to extract a value for aspect ratio at the location of each well. The data integration engine 205 can then derive a vertical length scale based on the extracted value for aspect ratio. The vertical length scale can be passed to the well extraction/isolation module 235 for use in performing operations specific to that module.

The well extraction/isolation module 235 can implement a step(s) of the algorithm 300 for extracting or isolating particular portions of information that pertain to wells in a subsurface region (308). In some implementations, orientation information for wells exists in the form of structural dip and dip azimuths keyed to depths. Example illustrations for this concept are discussed later with reference to FIGS. 9A and 9B. In general, structural dip and strike (or dip azimuth) are commonly-used components of a vector that describes structural orientation (see FIG. 9A). These data can be derived from downhole tools such as dipmeters or image logs and can be acquired using one or more well logging programs.

Like maps that are derived from seismic data, well structural information is multi-scale in character. For example, the well structural information can have short-wavelength noise superimposed on geological structures of various wavelengths. The well extraction/isolation module 235 can determine or compute approximations for the vertical length scale of interest from the structural fold aspect ratio obtained at (306). An example illustration for this concept is also discussed later with reference to FIG. 9B. In some implementations, the well extraction/isolation module 235 use an example smoothing method, such as one that is appropriate for vector (spherical) data, to correctly isolate information at the required length scale. The well extraction/isolation module 235 can use one or more known techniques to apply the smoothing method. Examples of smoothing methods include spherical statistical averaging and low-pass filtering.

The structural integration module 240 can implement a step(s) of the algorithm 300 for performing structural integration of seismic and well data (310). After obtaining structural information at the required vertical (for wells) length scale from a well, the data integration engine 205 can tie the map of corresponding horizontal (seismic) length scale to the obtained well information by forcing the map of corresponding horizontal (seismic) length scale to match an orientation at a particular position of the well on the map.

The implementation of forced matching of depth and orientation of a seismic map to well information can be done by obtaining local least-squares fit of a small planar patch to the nine grid nodes surrounding, and including, that closest to the subject well. The structural integration module 240 uses orientation of such a fitted patch to establish an angular distortion between the seismic map and the well information. The structural integration module 240 determines an updated patch, at least by reducing the orientation discrepancy between the fitted patch and the well orientation to zero, that yields a secondary correction factor (over and above the depth discrepancy) at the grid nodes surrounding the new well, forcing the structure to locally match the structure seen in the well.

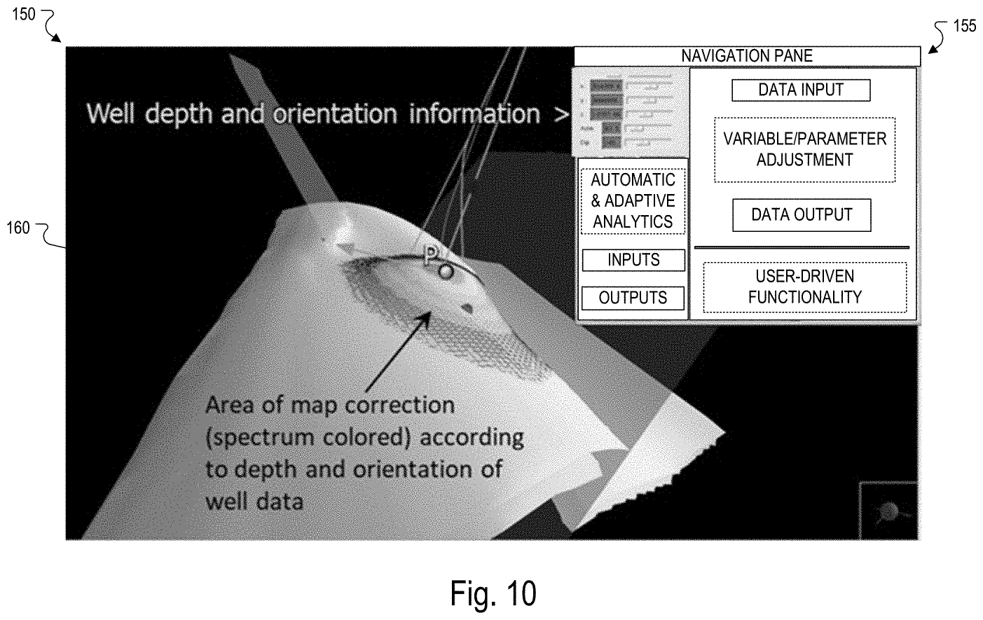

The structural integration module 240 implements repetition of this patch fitting and correction exercise at progressively more distant locations from the well, combined with smoothing, and the depth distortion correction. The repetition and combination of these processes leads to an overall depth distortion correction patch around the well that also honors the required structural orientation as seen in the well (see e.g., FIG. 10). Within this procedure, parameters such as map view anisotropy of the structural correction, and intensity of structural correction with radial distance from the well, can be default machined-determined parameters or under user control. An example illustration relating to this concept is discussed later with reference to FIG. 10.

The orientation ties can be achieved in a smooth manner. For example, the orientation ties can be achieved without abrupt local spike anomalies at the wells. The accomplish this the structural integration module 240 can be used to reduce a corresponding correction radially, and gradually, away from the well location to zero correction at a specified distance. The structural integration module 240 can determine or compute that a practical default value for this radius of influence is half the structural wavelength at that location. In some implementations, this determined value can be overridden at a users' discretion.

As described earlier, the algorithm 300 can be used to yield a length-scale specific structural orientation correction. In some implementations, the data integration engine 205 uses the algorithm 300 to calculate a single representative correction that takes into account some (or all) of the dominant length scales identified at (302) and (304). In one case, the single representative correction may be calculated at the expense of not producing an exact tie at a given length scale. In this case, the data integration engine 205 can use the algorithm 300 to apply multi-objective optimization to minimize the correction factor across all the length scales.

In some examples, the objective functions correspond to one or more of the workflows described in this disclosure for correcting a seismic map to a well at a given natural scale. In this specific case, one or more of the objective functions are used to simultaneously consider the corrections in depth and orientation required to correct the seismic map at two or more scales. In some cases correction factors may not be equal for each natural scale. Applying multi-objective optimization can be used to simultaneously consider several scales and determine correction for depth and orientation that, while not providing an exact match to the well at any one given scale, minimizes the distortion across a range of scales.

For example, rather than focusing on a specific scale, the structural integration module 240 can be used to employ a selection of a range of scales based on user discretion. This approach can be used, for instance, when it is unclear which scale at which to isolate orientation information from the well. In an example, restricted implementation, the correction factor can be minimized for the next shorter and next longer length scales to the length scale of interest. The advantage of a single, multi-scale correction factor is that it can be less susceptible to anomalies that arise from considering a single-scale correction.

In some implementations, a multi-objective optimization (310) is applied to determine a structural correction that ties the seismic map to the well information by accounting for the multi-scale structure of the seismic map and well information. As noted earlier, although the example of FIG. 3 indicates the algorithm 300 includes five steps, in some examples the algorithm 300 can include more or fewer steps. For example, the data integration engine 205 may combine two or more steps of algorithm 300 or may repeat or iterate performance of a particular step.

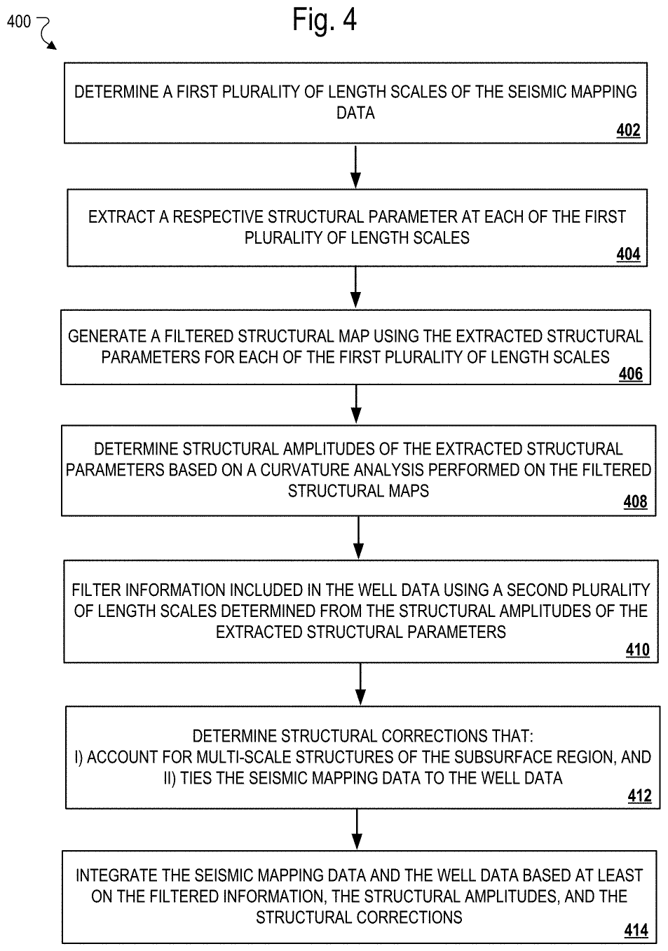

FIG. 4 illustrates an example process 400 for performing data integration using the example algorithm of FIG. 3. More specifically, process 400 provides an improved approach to performing adaptive multi-scale geological modeling and well integration. For example, process 400 provides a workflow or method for integrating seismic mapping data and well data for a subsurface region that includes a reservoir.

Process 400 can be implemented or executed using the computer systems 124 and the data integration engine 205 of a system 200. Hence, descriptions of process 400 may reference the computing resources of computer systems 124 and the data integration engine 205 described earlier in this document. In some implementations, the steps or actions included in process 400 are enabled by programmed firmware or software instructions, which are executable by one or more processors of the devices and resources described in this document.

Referring now to process 400, the system 200 determines first length scales of the seismic mapping data (402). For example, based on the seismic mapping data, the scaling selection module 220 can determine which scales of a structure are present and determine the first length scales from these scales. The seismic map or seismic mapping data can be obtained from a seismic survey performed in accordance with processes described earlier with reference to FIG. 1.

In some implementations, the scaling selection module 220 determines the first length scales as a dominant, or natural, length scale of a structure in a subsurface layer mapped from seismic reflection data. For example, the scaling selection module 220 can apply a technique that treats cross section information from seismic mapping data as curves and performs scale space analysis on those curves. In some cases, the data integration engine 205 uses a natural scale extraction technique to determine the first length scales. The first length scales can include horizontal length scales of a structure as seen on seismic maps.

The system 200 extracts a respective structure at each of the first length scales (404). The respective structure is a structural parameter(s), such as a “structural wavelength” or “natural scales.” For example, the system (200) can identify or determine which structural wavelengths are meaningful signals within a total information content of the seismic map. The spatial filtering module 225 can use (or select from) one or more filtering operations for isolating and/or extracting geological structures at a given scale.

The filtering operations can include techniques such as bandpass filtering, resampling, smoothing and Fast Fourier Transforms, or combinations of these. For example, the spatial filtering module 225 can apply such filters at least by taking the initial seismic map, which contains subsurface structural information in the form of a grid (e.g., x,y,z coordinates, usually evenly sampled in the x and y directions, with all units in meters or a similar measure of distance), and applying one or more filtering methods to a copy of this grid, usually within a computer application.

For instance, a smoothing filter can be used to reassign a given depth value of a grid node according to the average of the grid node depth values in a patch around the grid node. The size of the patch and the weighting of the adjacent grid nodes in this average determine the particular type of smoothing, such as box car or gaussian. Alternative filters, such as Fast Fourier Transform, can be applied in a similar manner, based on the algorithm or computational approach that is appropriate for that filter. In some (or all) cases, the output grid is a realization of the seismic depth map with a certain spatial length scale bandwidth removed, which could be removal of short wavelength information, long wavelength information, or both.

The removal operation yields an isolated bandwidth which can contain the structural information at the desired length scale. In some implementations, the spatial filtering module 225 applies at least one spatial filtering technique to generate versions of a structural map (derived from the seismic data) with information content restricted to the determined first length scales, such as one or more dominant spatial length scales.

The system 200 generates a filtered structural map using the extracted structures for each of the first length scales (406). The system 200 generates the filtered structural map as a product or output of the process performed using spatial filtering module 225. For example, the process includes system 200 identifying the length scales of interest using natural scales or a similar technique, and then filtering the depth map to restrict the information content. The isolated structural wavelength in the derived (filtered) seismic map can be represented by several spatially isolated structures and these are an output from the process. For clarity, here the word “isolated” should be interpreted in relation to isolating a given structural wavelength, is what the process does, as opposed to an isolated structure, which could refer to a singular structure in a seismic map.

The system 200 determines structural amplitudes of the extracted structures based on a curvature analysis performed on the filtered structural maps (408). The purpose of these structural amplitudes is to provide a proxy for vertical length scale, to be used in filtering the well data (410). The curvature analysis module 230 can determine the structural amplitudes in accordance with aspect ratios for the extracted structures (e.g., geological fold structures), where an aspect ratio can be defined as the ratio of structural amplitude to wavelength. For example, structural wavelengths and amplitudes, and hence aspect ratios at a given length scale, can be isolated by curvature analysis. The curvature analysis module 230 can compute or extract a value for aspect ratio at a location of each well and derive a vertical length scale based on the extracted value for aspect ratio. In some implementations, the curvature analysis is applied by the curvature analysis module 230 using techniques that involve osculating circles, differential geometry, or both.

The system 200 filters information included in the well data (235) using second length scales defined in the vertical direction, determined from the structural amplitudes of the extracted structures (410). For example, as described earlier with reference to FIG. 3, the system 200 can apply a smoothing or filtering operation to smooth (or filter) the well data, specifically orientation data, in a manner that is similar to the seismic map processing. However, in the wells the system operates on a 1D dataset, e.g., with datapoints that are spread along the wellbore which, nominally, can be straight and vertical.

The system 200 determines one or more structural corrections (412). For example, the system 200 determines one or more structural corrections for the well data, where the structural corrections: i) account for multi-scale structures of the subsurface region and ii) ties the seismic mapping data to the well data. In some implementations, the system 200 determines one or more length-scale specific structural orientation corrections. The system 200 also determines one or more structural corrections for the well data based on an optimization scheme, such as the multi-objective optimization process described earlier. In some implementations, determining the structural corrections include calculating a single representative correction that accounts for the multiple dominant length scales, but at the expense of not producing an exact tie at a given length scale.

The system 200 integrates the seismic mapping data and the well data based at least on the filtered information, the structural amplitudes, and the structural corrections (414). For example, the data integration engine 205 obtains structural information from the filtered information included in the well data. The structural information is obtained at a particular vertical length scale that associated with a well. The data integration engine 205 ties, links, or otherwise relates a seismic map of a corresponding horizontal length scale to the well at least by matching an orientation at a position of the well on the seismic map. For example, the structural integration module 240 can mathematical tie or relate subsurface measurements obtained for a wellbore (e.g., in depth) and seismic data (e.g., measured in time). The structural integration module 240 integrates the seismic mapping data and the well data by tying the seismic map of the corresponding horizontal length scale to the well based at least on mathematical operation.

The system 200 generates an output representing the integrated seismic mapping data and the well data. The output can be an integrated map 250 of subsurface geological structures with structural information at a user-specified length scale. The geological structures can be locations between wells of a subsurface region that includes a reservoir or body of rock that has sufficient porosity and permeability to store and transmit fluids. In some implementations, the integrated map 250 matches relevant structural depths and orientation information in wells that are located in an area of the subsurface region represented by the input map (for example, a seismic map) or the integrated map. A well-logging operation can be performed at a production site that is determined, selected, or otherwise identified based on the integrated map. In some implementations, the system 124 determines a production site for a well based on seismic and well-based structural information of the integrated map.

FIGS. 5A-5C illustrate example curvature and scale space data for a surface region such as the coastline of Africa. For example, FIGS. 5A-5C indicate scale space analysis of a multi-scale structure. The example of FIG. 5A shows a 2D curve corresponding to an input sample, whereas the example of FIG. 5B shows a scale space version of FIG. 5A. The scale space version shown at FIG. 5B can be produced by tracking locations of zero curvature during progressive Gaussian smoothing applied to the input sample 510. The progressive Gaussian smoothing can be applied using the data integration engine 205 described earlier and can include multiple representative scales. The example of FIG. 5C shows versions of the input sample 510 that correspond to arbitrary representative scales (for example 1-6) that were described with reference to FIG. 5B. In some implementations, the same analytical principles used with the surface region examples of FIGS. 5A-5C apply also to a cross section of a geological horizon in the subsurface.

FIGS. 6A and 6B illustrate example scale data for a subsurface region. More specifically, FIG. 6A is version of FIG. 5B, which highlights natural scales as indicated at least at 602, 604, and 606, whereas FIG. 6B shows example scale space manifolds identifying dominant length scales that are indicate at features 1, 2, 3, 4, 5 along the “scale space” axis of FIG. 6B. In some implementations, these dominant length scales are produced by a blob feature detection.

FIG. 7 is example data showing length scale isolation. This example data conveyed at FIG. 7 can be produced by utilizing resampling, smoothing, Fast Fourier Transforms (FFT), or a combination of these. The numbers shown in each box, e.g., “a) 25 m,” “b) 100 m,” “c) 250 m,” represent the low-pass filter that has been applied in producing these examples. For example, in each case, structural information with shorter spatial wavelength than these distances has been removed.

FIGS. 8A-8D illustrate example information and data associated with curvature analysis of a length scale filtered surface. More specifically, FIG. 8A shows examples of nomenclature associated with curvature in the line of section, whereas FIG. 8B is a graphic that shows an example realization of a filtered surface. The example of FIG. 8C is a graphic that shows a mean curvature of the graphic of FIG. 8B, whereas FIG. 8D shows example structural domains of FIG. 8B that are isolated by curvature characteristics.

FIG. 9A shows example data for a geological layer orientation as may be recorded in well information such as a dipmeter or image log. More specifically, the example of FIG. 9A provides a definition of strike and dip components of geological layer orientation. FIG. 9B shows example information for a geological structure. More specifically, the information conveyed in the example of FIG. 9B pertains to use of geological structure aspect ratio (a/λ). The aspect ratio can be used to estimate vertical length scale of structural information from well measurements that are relevant to the subject horizontal length scale in the map.

FIG. 10 shows an example graphical interface 150 of an application that can be used to integrate structural data in accordance with the techniques described in this document. For example, interface 150 can correspond to a workstation screenshot of an application program used to implement operations of the data integration engine 205. In the example of FIG. 10, the graphical interface 150 includes a data output such as a mapping graphic 160 showing a spectrum colored area of map correction according to depth and orientation information obtained from a sample set of well data.

In some implementations, the application program, in part via interface 150, integrates user-driven (and automated) functionality to tie seismic map grids to wells in depth and orientation with one or more multi-scale or natural scale analysis tools. The application program and interface 150 can be used to automatically perform such analysis in a default or adaptive manner. Example controls associated with the functionality and analysis tools are indicated at interface block 155. The controls and functionality of the interface 150 and corresponding application builds on the purely-manual, uninformed functionality of existing approaches, for example, to provide 1) natural-scale guidance for how to size a well tie and 2) offer choices for automating the overall process.

FIG. 11 is a block diagram of an example computer system 900 used to provide computational functionalities associated with described algorithms, methods, functions, processes, flows, and procedures described in the present disclosure, according to some implementations of the present disclosure.

The illustrated computer 902 is intended to encompass any computing device such as a server, a desktop computer, a laptop/notebook computer, a wireless data port, a smart phone, a personal data assistant (PDA), a tablet computing device, or one or more processors within these devices, including physical instances, virtual instances, or both. The computer 902 can include input devices such as keypads, keyboards, and touch screens that can accept user information. Also, the computer 902 can include output devices that can convey information associated with the operation of the computer 902. The information can include digital data, visual data, audio information, or a combination of information. The information can be presented in a graphical user interface (UI) (or GUI).

The computer 902 can serve in a role as a client, a network component, a server, a database, a persistency, or components of a computer system for performing the subject matter described in the present disclosure. The illustrated computer 902 is communicably coupled with a network 930. In some implementations, one or more components of the computer 902 can be configured to operate within different environments, including cloud-computing-based environments, local environments, global environments, and combinations of environments.

Generally, the computer 902 is an electronic computing device operable to receive, transmit, process, store, and manage data and information associated with the described subject matter. According to some implementations, the computer 902 can also include, or be communicably coupled with, an application server, an email server, a web server, a caching server, a streaming data server, or a combination of servers.

The computer 902 can receive requests over network 930 from a client application (for example, executing on another computer 902). The computer 902 can respond to the received requests by processing the received requests using software applications. Requests can also be sent to the computer 902 from internal users (for example, from a command console), external (or third) parties, automated applications, entities, individuals, systems, and computers.

Each of the components of the computer 902 can communicate using a system bus 903. In some implementations, any or all of the components of the computer 902, including hardware or software components, can interface with each other or the interface 904 (or a combination of both), over the system bus 903. Interfaces can use an application programming interface (API) 912, a service layer 913, or a combination of the API 912 and service layer 913. The API 912 can include specifications for routines, data structures, and object classes. The API 912 can be either computer-language independent or dependent. The API 912 can refer to a complete interface, a single function, or a set of APIs.

The service layer 913 can provide software services to the computer 902 and other components (whether illustrated or not) that are communicably coupled to the computer 902. The functionality of the computer 902 can be accessible for all service consumers using this service layer. Software services, such as those provided by the service layer 913, can provide reusable, defined functionalities through a defined interface. For example, the interface can be software written in JAVA, C++, or a language providing data in extensible markup language (XML) format. While illustrated as an integrated component of the computer 902, in alternative implementations, the API 912 or the service layer 913 can be stand-alone components in relation to other components of the computer 902 and other components communicably coupled to the computer 902. Moreover, any or all parts of the API 912 or the service layer 913 can be implemented as child or sub-modules of another software module, enterprise application, or hardware module without departing from the scope of the present disclosure.

The computer 902 includes an interface 904. Although illustrated as a single interface 904 in FIG. 9, two or more interfaces 904 can be used according to particular needs, desires, or particular implementations of the computer 902 and the described functionality. The interface 904 can be used by the computer 902 for communicating with other systems that are connected to the network 930 (whether illustrated or not) in a distributed environment. Generally, the interface 904 can include, or be implemented using, logic encoded in software or hardware (or a combination of software and hardware) operable to communicate with the network 930. More specifically, the interface 904 can include software supporting one or more communication protocols associated with communications. As such, the network 930 or the interface's hardware can be operable to communicate physical signals within and outside of the illustrated computer 902.

The computer 902 includes a processor 905. Although illustrated as a single processor 905 in FIG. 9, two or more processors 905 can be used according to particular needs, desires, or particular implementations of the computer 902 and the described functionality. Generally, the processor 905 can execute instructions and can manipulate data to perform the operations of the computer 902, including operations using algorithms, methods, functions, processes, flows, and procedures as described in the present disclosure.

The computer 902 also includes a database 906 that can hold data, including seismic data 916 (for example, seismic data described earlier at least with reference to FIG. 1), for the computer 902 and other components connected to the network 930 (whether illustrated or not). For example, database 906 can be an in-memory, conventional, or a database storing data consistent with the present disclosure. In some implementations, database 906 can be a combination of two or more different database types (for example, hybrid in-memory and conventional databases) according to particular needs, desires, or particular implementations of the computer 902 and the described functionality. Although illustrated as a single database 906 in FIG. 9, two or more databases (of the same, different, or combination of types) can be used according to particular needs, desires, or particular implementations of the computer 902 and the described functionality. While database 906 is illustrated as an internal component of the computer 902, in alternative implementations, database 906 can be external to the computer 902.

The computer 902 also includes a memory 907 that can hold data for the computer 902 or a combination of components connected to the network 930 (whether illustrated or not). Memory 907 can store any data consistent with the present disclosure. In some implementations, memory 907 can be a combination of two or more different types of memory (for example, a combination of semiconductor and magnetic storage) according to particular needs, desires, or particular implementations of the computer 902 and the described functionality. Although illustrated as a single memory 907 in FIG. 9, two or more memories 907 (of the same, different, or combination of types) can be used according to particular needs, desires, or particular implementations of the computer 902 and the described functionality. While memory 907 is illustrated as an internal component of the computer 902, in alternative implementations, memory 907 can be external to the computer 902.

The application 908 can be an algorithmic software engine providing functionality according to particular needs, desires, or particular implementations of the computer 902 and the described functionality. For example, application 908 can serve as one or more components, modules, or applications. Further, although illustrated as a single application 908, the application 908 can be implemented as multiple applications 908 on the computer 902. In addition, although illustrated as internal to the computer 902, in alternative implementations, the application 908 can be external to the computer 902.

The computer 902 can also include a power supply 914. The power supply 914 can include a rechargeable or non-rechargeable battery that can be configured to be either user- or non-user-replaceable. In some implementations, the power supply 914 can include power-conversion and management circuits, including recharging, standby, and power management functionalities. In some implementations, the power-supply 914 can include a power plug to allow the computer 902 to be plugged into a wall socket or a power source to, for example, power the computer 902 or recharge a rechargeable battery.

There can be any number of computers 902 associated with, or external to, a computer system containing computer 902, with each computer 902 communicating over network 930. Further, the terms “client,” “user,” and other appropriate terminology can be used interchangeably, as appropriate, without departing from the scope of the present disclosure. Moreover, the present disclosure contemplates that many users can use one computer 902 and one user can use multiple computers 902.

Implementations of the subject matter and the functional operations described in this specification can be implemented in digital electronic circuitry, in tangibly embodied computer software or firmware, in computer hardware, including the structures disclosed in this specification and their structural equivalents, or in combinations of one or more of them. Software implementations of the described subject matter can be implemented as one or more computer programs. Each computer program can include one or more modules of computer program instructions encoded on a tangible, non-transitory, computer-readable computer-storage medium for execution by, or to control the operation of, data processing apparatus. Alternatively, or additionally, the program instructions can be encoded in/on an artificially generated propagated signal. The example, the signal can be a machine-generated electrical, optical, or electromagnetic signal that is generated to encode information for transmission to suitable receiver apparatus for execution by a data processing apparatus. The computer-storage medium can be a machine-readable storage device, a machine-readable storage substrate, a random or serial access memory device, or a combination of computer-storage mediums.

The terms “data processing apparatus,” “computer,” and “electronic computer device” (or equivalent as understood by one of ordinary skill in the art) refer to data processing hardware. For example, a data processing apparatus can encompass all kinds of apparatus, devices, and machines for processing data, including by way of example, a programmable processor, a computer, or multiple processors or computers. The apparatus can also include special purpose logic circuitry including, for example, a central processing unit (CPU), a field programmable gate array (FPGA), or an application specific integrated circuit (ASIC). In some implementations, the data processing apparatus or special purpose logic circuitry (or a combination of the data processing apparatus or special purpose logic circuitry) can be hardware- or software-based (or a combination of both hardware- and software-based). The apparatus can optionally include code that creates an execution environment for computer programs, for example, code that constitutes processor firmware, a protocol stack, a database management system, an operating system, or a combination of execution environments. The present disclosure contemplates the use of data processing apparatuses with or without conventional operating systems, for example, LINUX, UNIX, WINDOWS, MAC OS, ANDROID, or IOS.

A computer program, which can also be referred to or described as a program, software, a software application, a module, a software module, a script, or code, can be written in any form of programming language. Programming languages can include, for example, compiled languages, interpreted languages, declarative languages, or procedural languages. Programs can be deployed in any form, including as stand-alone programs, modules, components, subroutines, or units for use in a computing environment. A computer program can, but need not, correspond to a file in a file system. A program can be stored in a portion of a file that holds other programs or data, for example, one or more scripts stored in a markup language document, in a single file dedicated to the program in question, or in multiple coordinated files storing one or more modules, sub programs, or portions of code. A computer program can be deployed for execution on one computer or on multiple computers that are located, for example, at one site or distributed across multiple sites that are interconnected by a communication network. While portions of the programs illustrated in the various figures may be shown as individual modules that implement the various features and functionality through various objects, methods, or processes, the programs can instead include a number of sub-modules, third-party services, components, and libraries. Conversely, the features and functionality of various components can be combined into single components as appropriate. Thresholds used to make computational determinations can be statically, dynamically, or both statically and dynamically determined.

The methods, processes, or logic flows described in this specification can be performed by one or more programmable computers executing one or more computer programs to perform functions by operating on input data and generating output. The methods, processes, or logic flows can also be performed by, and apparatus can also be implemented as, special purpose logic circuitry, for example, a CPU, an FPGA, or an ASIC.

Computers suitable for the execution of a computer program can be based on one or more of general and special purpose microprocessors and other kinds of CPUs. The elements of a computer are a CPU for performing or executing instructions and one or more memory devices for storing instructions and data. Generally, a CPU can receive instructions and data from (and write data to) a memory. A computer can also include, or be operatively coupled to, one or more mass storage devices for storing data. In some implementations, a computer can receive data from, and transfer data to, the mass storage devices including, for example, magnetic, magneto optical disks, or optical disks. Moreover, a computer can be embedded in another device, for example, a mobile telephone, a personal digital assistant (PDA), a mobile audio or video player, a game console, a global positioning system (GPS) receiver, or a portable storage device such as a universal serial bus (USB) flash drive.

Computer readable media (transitory or non-transitory, as appropriate) suitable for storing computer program instructions and data can include all forms of permanent/non-permanent and volatile/non-volatile memory, media, and memory devices. Computer readable media can include, for example, semiconductor memory devices such as random access memory (RAM), read only memory (ROM), phase change memory (PRAM), static random access memory (SRAM), dynamic random access memory (DRAM), erasable programmable read-only memory (EPROM), electrically erasable programmable read-only memory (EEPROM), and flash memory devices. Computer readable media can also include, for example, magnetic devices such as tape, cartridges, cassettes, and internal/removable disks. Computer readable media can also include magneto optical disks and optical memory devices and technologies including, for example, digital video disc (DVD), CD ROM, DVD+/−R, DVD-RAM, DVD-ROM, HD-DVD, and BLURAY. The memory can store various objects or data, including caches, classes, frameworks, applications, modules, backup data, jobs, web pages, web page templates, data structures, database tables, repositories, and dynamic information. Types of objects and data stored in memory can include parameters, variables, algorithms, instructions, rules, constraints, and references. Additionally, the memory can include logs, policies, security or access data, and reporting files. The processor and the memory can be supplemented by, or incorporated in, special purpose logic circuitry.

Implementations of the subject matter described in the present disclosure can be implemented on a computer having a display device for providing interaction with a user, including displaying information to (and receiving input from) the user. Types of display devices can include, for example, a cathode ray tube (CRT), a liquid crystal display (LCD), a light-emitting diode (LED), and a plasma monitor. Display devices can include a keyboard and pointing devices including, for example, a mouse, a trackball, or a trackpad. User input can also be provided to the computer through the use of a touchscreen, such as a tablet computer surface with pressure sensitivity or a multi-touch screen using capacitive or electric sensing. Other kinds of devices can be used to provide for interaction with a user, including to receive user feedback including, for example, sensory feedback including visual feedback, auditory feedback, or tactile feedback. Input from the user can be received in the form of acoustic, speech, or tactile input. In addition, a computer can interact with a user by sending documents to, and receiving documents from, a device that is used by the user. For example, the computer can send web pages to a web browser on a user's client device in response to requests received from the web browser.

The term “graphical user interface,” or “GUI,” can be used in the singular or the plural to describe one or more graphical user interfaces and each of the displays of a particular graphical user interface. Therefore, a GUI can represent any graphical user interface, including, but not limited to, a web browser, a touch screen, or a command line interface (CLI) that processes information and efficiently presents the information results to the user. In general, a GUI can include a plurality of user interface (UI) elements, some or all associated with a web browser, such as interactive fields, pull-down lists, and buttons. These and other UI elements can be related to or represent the functions of the web browser.

Implementations of the subject matter described in this specification can be implemented in a computing system that includes a back end component, for example, as a data server, or that includes a middleware component, for example, an application server. Moreover, the computing system can include a front-end component, for example, a client computer having one or both of a graphical user interface or a Web browser through which a user can interact with the computer. The components of the system can be interconnected by any form or medium of wireline or wireless digital data communication (or a combination of data communication) in a communication network. Examples of communication networks include a local area network (LAN), a radio access network (RAN), a metropolitan area network (MAN), a wide area network (WAN), Worldwide Interoperability for Microwave Access (WIMAX), a wireless local area network (WLAN) (for example, using 802.11 a/b/g/n or 802.20 or a combination of protocols), all or a portion of the Internet, or any other communication system or systems at one or more locations (or a combination of communication networks). The network can communicate with, for example, Internet Protocol (IP) packets, frame relay frames, asynchronous transfer mode (ATM) cells, voice, video, data, or a combination of communication types between network addresses.

The computing system can include clients and servers. A client and server can generally be remote from each other and can typically interact through a communication network. The relationship of client and server can arise by virtue of computer programs running on the respective computers and having a client-server relationship. Cluster file systems can be any file system type accessible from multiple servers for read and update. Locking or consistency tracking may not be necessary since the locking of exchange file system can be done at application layer. Furthermore, Unicode data files can be different from non-Unicode data files.

While this specification contains many specific implementation details, these should not be construed as limitations on the scope of what may be claimed, but rather as descriptions of features that may be specific to particular implementations. Certain features that are described in this specification in the context of separate implementations can also be implemented, in combination, in a single implementation. Conversely, various features that are described in the context of a single implementation can also be implemented in multiple implementations, separately, or in any suitable sub-combination. Moreover, although previously described features may be described as acting in certain combinations and even initially claimed as such, one or more features from a claimed combination can, in some cases, be excised from the combination, and the claimed combination may be directed to a sub-combination or variation of a sub-combination.

Particular implementations of the subject matter have been described. Other implementations, alterations, and permutations of the described implementations are within the scope of the following claims as will be apparent to those skilled in the art. While operations are depicted in the drawings or claims in a particular order, this should not be understood as requiring that such operations be performed in the particular order shown or in sequential order, or that all illustrated operations be performed (some operations may be considered optional), to achieve desirable results. In certain circumstances, multitasking or parallel processing (or a combination of multitasking and parallel processing) may be advantageous and performed as deemed appropriate.

Moreover, the separation or integration of various system modules and components in the previously described implementations should not be understood as requiring such separation or integration in all implementations, and it should be understood that the described program components and systems can generally be integrated together in a single software product or packaged into multiple software products.

Accordingly, the previously described example implementations do not define or constrain the present disclosure. Other changes, substitutions, and alterations are also possible without departing from the spirit and scope of the present disclosure.

Furthermore, any claimed implementation is considered to be applicable to at least a computer-implemented method; a non-transitory, computer-readable medium storing computer-readable instructions to perform the computer-implemented method; and a computer system comprising a computer memory interoperably coupled with a hardware processor configured to perform the computer-implemented method or the instructions stored on the non-transitory, computer-readable medium.

Particular embodiments of the subject matter have been described. Other embodiments are within the scope of the following claims. For example, the actions recited in the claims can be performed in a different order and still achieve desirable results. As one example, some processes depicted in the accompanying figures do not necessarily require the particular order shown, or sequential order, to achieve desirable results.

What is claimed is:

1. A method for integrating seismic mapping data and well data for a subsurface region comprising a reservoir, the method comprising:
determining a first plurality of length scales of the seismic mapping data;
extracting a respective structure at each of the first plurality of length scales;
generating a filtered structural map using the extracted structures for each of the first plurality of length scales;
determining structural amplitudes of the extracted structures based on a curvature analysis performed on the filtered structural maps;
filtering information included in the well data using a second plurality of length scales determined from the structural amplitudes of the extracted structures;
determining, for the well data and based on an optimization scheme, one or more structural corrections that:
i) account for multi-scale structures of the subsurface region, and
ii) ties the seismic mapping data to the well data;
based at least on the filtered information, the structural amplitudes, and the structural corrections, integrating the seismic mapping data and the well data; and
generating an output representing the integrated seismic mapping data and the well data.

2. The method of claim 1, wherein generating an output representing the integrated seismic mapping data and the well data comprises:
generating an integrated map of subsurface structures with structural information at a user-specified length scale,
wherein the integrated map matches relevant structural depths and orientation information in wells that are located in an area of the subsurface region represented by the integrated map.

3. The method of claim 2, wherein integrating the seismic mapping data and the well data comprises:
obtaining, from the filtered information included in the well data, structural information at a particular vertical length scale associated with a well;
tying a seismic map of a corresponding horizontal length scale to the well at least by matching an orientation at a position of the well on the seismic map; and
integrating the seismic mapping data and the well data at least by tying the seismic map of the corresponding horizontal length scale to the well.

4. The method of claim 3, wherein integrating the seismic mapping data and the well data comprises:
modifying a depth map derived from seismic interpretation over an area comprising the subsurface region, wherein the depth map is modified using depth and structural orientation information of the well data.

5. The method of claim 4, wherein the seismic mapping data comprises a mapped geological structure that is intermediate one or more wells and the method further comprises:
integrating the seismic mapping data and the well data without distorting a true structure of the mapped geological structure.

6. The method of claim 1, wherein determining one or more structural corrections comprises:
determining one or more length-scale specific structural orientation corrections.

7. The method of claim 6, wherein determining a first plurality of length scales comprises:
performing scale selection analysis on the seismic mapping data; and
determining a plurality of dominant length scales based on the scale selection analysis.

8. The method of claim 7, wherein determining one or more structural corrections comprises:
calculating a single representative correction that accounts for the plurality of dominant length scales.

9. The method of claim 7, further comprising:
applying a multi-objective optimization scheme to the filtered information derived from the well data; and
in response to applying the multi-objective optimization scheme, minimizing a correction factor across each of the second plurality of length scales.

10. The method of claim 1, wherein extracting a respective structure at each of the first plurality of length scales comprises:
applying a spatial filtering technique to the seismic mapping data with reference to the first plurality of length scales; and
extracting a respective structure at each of the first plurality of length scales in response to applying the spatial filtering technique to the seismic mapping data.

11. The method of claim 10, wherein the spatial filtering technique comprises a bandpass filter.

12. The method of claim 1, wherein:
the seismic mapping data comprises a map of subsurface structures in the form of a depth grid that is referenced to x,y spatial coordinates; and
the well data comprises well control locations with depth-dependent structures in the form of structural dip and dip direction.

13. The method of claim 1, wherein generating an output representing the integrated seismic mapping data and the well data comprises:
generating an imaging of subsurface geology for applications in: i) hydrocarbon production using the reservoir, ii) aquifer management, and iii) sequestration projects.

14. A system for integrating seismic mapping data and well data for a subsurface region comprising a reservoir, the system comprising a processing device and a non-transitory machine-readable storage device storing instructions that are executable by the processing device to cause performance of operations comprising:
determining a first plurality of length scales of the seismic mapping data;
extracting a respective structure at each of the first plurality of length scales;
generating a filtered structural map using the extracted structures for each of the first plurality of length scales;
determining structural amplitudes of the extracted structures based on a curvature analysis performed on the filtered structural maps;
filtering information included in the well data using a second plurality of length scales determined from the structural amplitudes of the extracted structures;
determining, for the well data and based on an optimization scheme, one or more structural corrections that:
i) account for multi-scale structures of the subsurface region, and
ii) ties the seismic mapping data to the well data;
based at least on the filtered information, the structural amplitudes, and the structural corrections, integrating the seismic mapping data and the well data; and
generating an output representing the integrated seismic mapping data and the well data.

15. The system of claim 14, wherein generating an output representing the integrated seismic mapping data and the well data comprises:
generating an integrated map of subsurface structures with structural information at a user-specified length scale,
wherein the integrated map matches relevant structural depths and orientation information in wells that are located in an area of the subsurface region represented by the integrated map.

16. The system of claim 15, wherein integrating the seismic mapping data and the well data comprises:
obtaining, from the filtered information included in the well data, structural information at a particular vertical length scale associated with a well;
tying a seismic map of a corresponding horizontal length scale to the well at least by matching an orientation at a position of the well on the seismic map; and
integrating the seismic mapping data and the well data at least by tying the seismic map of the corresponding horizontal length scale to the well.

17. The system of claim 16, wherein integrating the seismic mapping data and the well data comprises:
modifying a depth map derived from seismic interpretation over an area comprising the subsurface region, wherein the depth map is modified using depth and structural orientation information of the well data.

18. The system of claim 17, wherein the seismic mapping data comprises a mapped geological structure that is intermediate one or more wells and the operations further comprises:
integrating the seismic mapping data and the well data without distorting a true structure of the mapped geological structure.

19. The system of claim 14, wherein determining one or more structural corrections comprises:
determining one or more length-scale specific structural orientation corrections.

20. The system of claim 19, wherein determining a first plurality of length scales comprises:
performing scale selection analysis on the seismic mapping data; and
determining a plurality of dominant length scales based on the scale selection analysis.

21. The system of claim 20, wherein determining one or more structural corrections comprises:
calculating a single representative correction that accounts for the plurality of dominant length scales.

22. The system of claim 20, wherein the operations further comprise:
applying a multi-objective optimization scheme to the filtered information derived from the well data; and
in response to applying the multi-objective optimization scheme, minimizing a correction factor across each of the second plurality of length scales.

23. The system of claim 14, wherein extracting a respective structure at each of the first plurality of length scales comprises:
applying a spatial filtering technique to the seismic mapping data with reference to the first plurality of length scales; and
extracting a respective structure at each of the first plurality of length scales in response to applying the spatial filtering technique to the seismic mapping data.

24. The system of claim 23, wherein the spatial filtering technique comprises a bandpass filter.

25. The system of claim 14, wherein:
the seismic mapping data comprises a map of subsurface structures in the form of a depth grid that is referenced to x,y spatial coordinates; and
the well data comprises well control locations with depth-dependent structures in the form of structural dip and dip direction.

26. The system of claim 14, wherein generating an output representing the integrated seismic mapping data and the well data comprises:
generating an imaging of subsurface geology for applications in: i) hydrocarbon production using the reservoir, ii) aquifer management, and iii) sequestration projects.

27. The system of claim 14, wherein the operations further comprise:
performing seismic survey of the subsurface region; and
obtaining the seismic mapping data based the seismic survey.

28. The system of claim 14, wherein the operations further comprise:
performing well logging at a production site identified from an integrated map that corresponds to the output representing the integrated seismic mapping data and the well data.
